(19) United States
(12) Patent Application Publication
(10) Pub. No.: US 2012/0292777 A1
(43) Pub. Date: Nov. 22, 2012

(54) Backside Power Delivery Using Die Stacking

(76) Inventor: Jonathan P. Lotz, Fort Collins, CO (US)

(21) Appl. No.: 13/110,390

(22) Filed: May 18, 2011

(51) Int. Cl. H01L 23/48; H01L 21/762

(52) U.S. Cl. 257/774; 438/459; 257/E23.011; 257/E21.567

(57) ABSTRACT

In a stacked die device having an active circuit die bonded on top of a power delivery die using, circuit components formed on the active circuit die are connected to receive power from a coarse network of low resistance, high capacitance power and ground conductors in the power delivery die through conductive via structures or through silicon vias (TSVs) formed in the active circuit die so that primary power is provided from the backside of the active circuit die, leaving more resources and space in the metal interconnect structure for input/output signal routing.

### BACKGROUND OF THE INVENTION

1. Field of the Invention

The present invention relates in general to integrated circuits. In one aspect, the present invention relates to the fabrication of integrated circuit devices with improved power/ground connections.

2. Description of the Related Art

With today's high performance integrated circuit devices, millions of components (e.g., transistors, interconnects, pads, etc.) are integrated into a single wafer/die, and there is ongoing demand to improve chip performance by increasing the component density on the wafer/die while adding or maintaining the number of power supply and input/output (I/O) pins for each integrated circuit device, all while simultaneously improving electrical performance, increasing thermal dissipation, and reducing die size. However, there are a number of challenges associated with conventional fabrication techniques for connecting the power supply and I/O pins through multiple interconnect metal layers formed on top of the wafer/die. To illustrate these challenges, reference is now made FIG. 1 which depicts a top view 101 and side view 102 of a typical die in which active circuits formed on a wafer/substrate 100 are connected to signal lines S and power lines Vdd, GND through an interconnect structure formed in multiple metal layers (e.g., M1-M6). By bringing the reference voltages Vdd and GND down through power and ground interconnections (e.g., 110, 113, 114, 117, 118, 121) formed in multiple metal layers (e.g., M1-M6), circuit resistance and/or inter-electrode capacitance is increased, thereby reducing electrical performance. These problems are exacerbated when the power network is formed with fine vias between the metal interconnect levels. Another drawback associated with conventional power network designs is that a significant portion of the chip area (e.g., as much as 30 percent of the interconnect areas) must be used for power and ground delivery, although this number can vary depending on the power requirements for each layer. Conventional approaches for overcoming these challenges include increasing the size of the power network and the I/O lead requirements, leading to increased chip size and overall profile.

Accordingly, a need exists for an improved integrated circuit device and method for manufacturing same which addresses various problems in the art that have been discovered by the above-named inventor where various limitations and disadvantages of conventional solutions and technologies will become apparent to one of skill in the art after reviewing the remainder of the present application with reference to the drawings and detailed description which follow, though it should be understood that this description of the related art section is not intended to serve as an admission that the described subject matter is prior art.

### SUMMARY OF EMBODIMENTS

Broadly speaking, the present invention provides a stacked die architecture, device, system, and method of fabrication in which a power delivery wafer/die is integrated with an active wafer/die to vertically stack multiple integrated chips so that primary power is provided through backside vias formed in the active wafer/die. In selected embodiments, a power delivery wafer/die is stacked on the backside of the active wafer/die so that primary power (e.g., all or most of the power) is provided through the backside of the active wafer/die using through silicon vias (TSVs) formed in the active wafer/die. With this approach, backside power may be provided over a low resistance, high capacitance network by forming the power delivery wafer/die with coarse or thick metal conductor layers in high-k dielectric materials. This approach also greatly reduces or eliminates the metal contact resources on the front side of the active wafer/die that need to be dedicated to power/ground routing. In other embodiments, a power delivery wafer/die stacked on the backside of the active wafer/die receives power through the front side of the active wafer/die and distributes the power through the backside of the active wafer/die using TSVs formed in the active wafer/die. With this approach, the power/ground contact resources on the front side and the multi-layer interconnect stack of the active wafer/die are reduced significantly due to the addition of backside power delivery.

In selected example embodiments, a stacked die device and fabrication methodology are provided for routing primary power through the backside of an active circuit die. As disclosed, the stacked die device includes a power delivery die with power and ground conductors for connection to one or more external power and ground sources. Formed on the power delivery die is an active circuit die having power and ground routings which are connected to circuit components formed on the active circuit die and to receive power from the power and ground conductors in the power delivery die through a first plurality of conductive via structures (e.g., coarse through silicon vias formed in a silicon substrate) formed in the active circuit die. In operation, the power delivery die provides backside power to the active circuit die with a network of low resistance, high capacitance power and ground conductors for connecting the one or more external power and ground sources to the first plurality of conductive via structures formed in the active circuit die. The power delivery die may include power and ground conductors formed in one or more high-k dielectric layers on a base substrate layer for connecting the external power and ground sources to the first plurality of conductive via structures formed in the active circuit die. The power delivery die may also include a plurality of conductive via structures formed in the base substrate layer for connecting the power conductor and a ground conductor to the external power and ground sources. In addition or in the alternative, the active circuit die may include a metal interconnect structure with signal input/output lines, a conductive power contact structure, and a conductive ground contact structure for connecting the external power and ground sources to the power and ground conductors in the power delivery die, in which case all of the metal interconnect structure may be used to connect the plurality of signal input/output lines to the circuit components except for the conductive power contact structure and the conductive ground contact structure. Alternatively, the entirety of the metal interconnect structure formed on a substrate layer may be used to connect the plurality of signal input/output lines to the circuit components when power is delivered from the backside of the power delivery die. In selected embodiments, a metal interconnect structure formed on the active circuit die includes first and second conductor layers formed at the periphery of the metal interconnect structure for bringing power and ground voltages down through multiple metal layers in the metal interconnect structure for delivery to the power and ground conductors in the power delivery die. In other embodiments, the power delivery die includes a plurality of through silicon via structures formed peripherally around a base silicon substrate layer for bringing power and ground voltages through the base silicon substrate layer for delivery to the power and ground conductors in the power delivery die.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 illustrates a simplified top and side view of a typical die in which active circuits formed on a wafer are connected to I/O signal and power lines through an interconnect structure formed in multiple metal layers on the front side of the wafer;

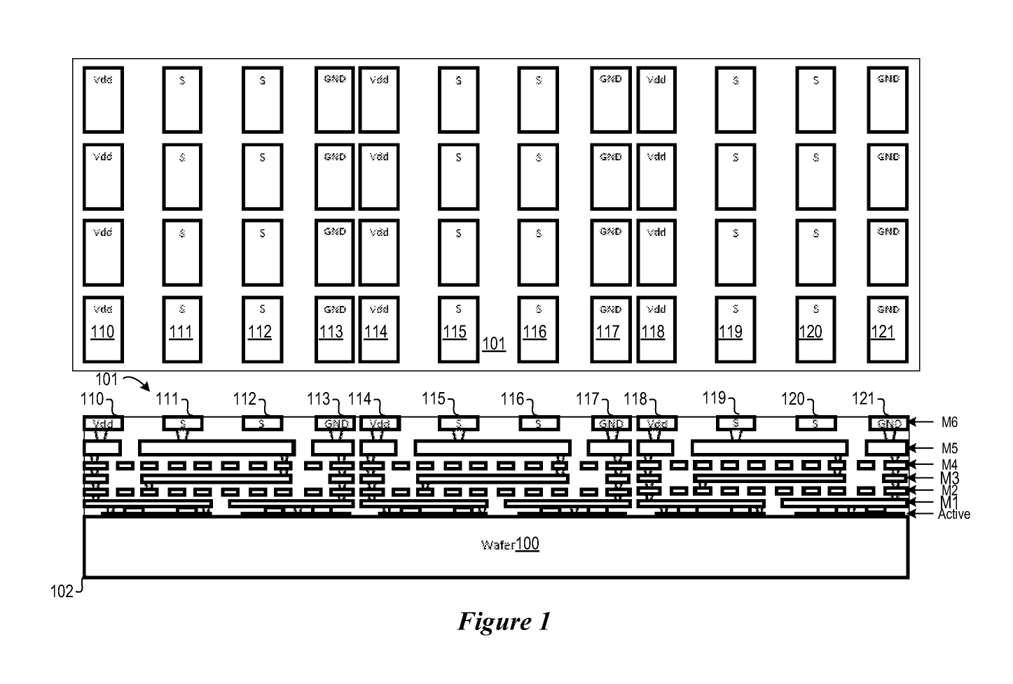

FIG. 2 illustrates a simplified top and side view of a stacked wafer/die in which active circuits formed on an active wafer/die are connected to power lines through backside through silicon vias and a power delivery wafer attached to the backside of the active wafer/die;

FIG. 3 illustrates a simplified plan view of the peripheral power connect vias formed in the backside of the base wafer substrate of the power delivery wafer structure; and

FIG. 4 illustrates a simplified top and side view of a stacked wafer/die in which a power delivery wafer/die stacked on the backside of the active wafer/die receives power through the front side of the active wafer/die and distributes the power through the backside of the active wafer/die using TSVs formed in the active wafer/die.

### DETAILED DESCRIPTION

A stacked power delivery die and method of fabrication are described wherein the stacked power delivery die provides power through TSV structures formed in the backside of an active die to provide a robust power and ground network for the active die while reducing or eliminating the power/ground conductors formed on the front side of the active die. By forming a large number of backside TSV power connections in the active die and bonding the backside of the active die to a power delivery die that includes a coarse network of low resistance, high capacitance power conductors formed with thick metallization (and possibly integrated capacitors), primary power is delivered through the backside of the active die and interconnect structures on the front side of the active die are available for additional signals lines. In selected embodiments, the power delivery die would provide the primary power network and connect to the power network of the active die through fine grained TSVs. The power delivery die would also connect to the package power planes through bumps around the periphery, TSVs at the periphery, wire bonds, or could itself have coarse grained TSVs for power and I/O connections.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional and top view depictions of an integrated circuit device without including every device feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the integrated circuit device. Where the specific procedures for forming or removing such materials are not detailed below, conventional techniques to one skilled in the art for growing, depositing, removing, etching or otherwise forming such layers at appropriate dimensions shall be intended. Such details are well known and not considered necessary to teach one skilled in the art of how to make or use the present invention.

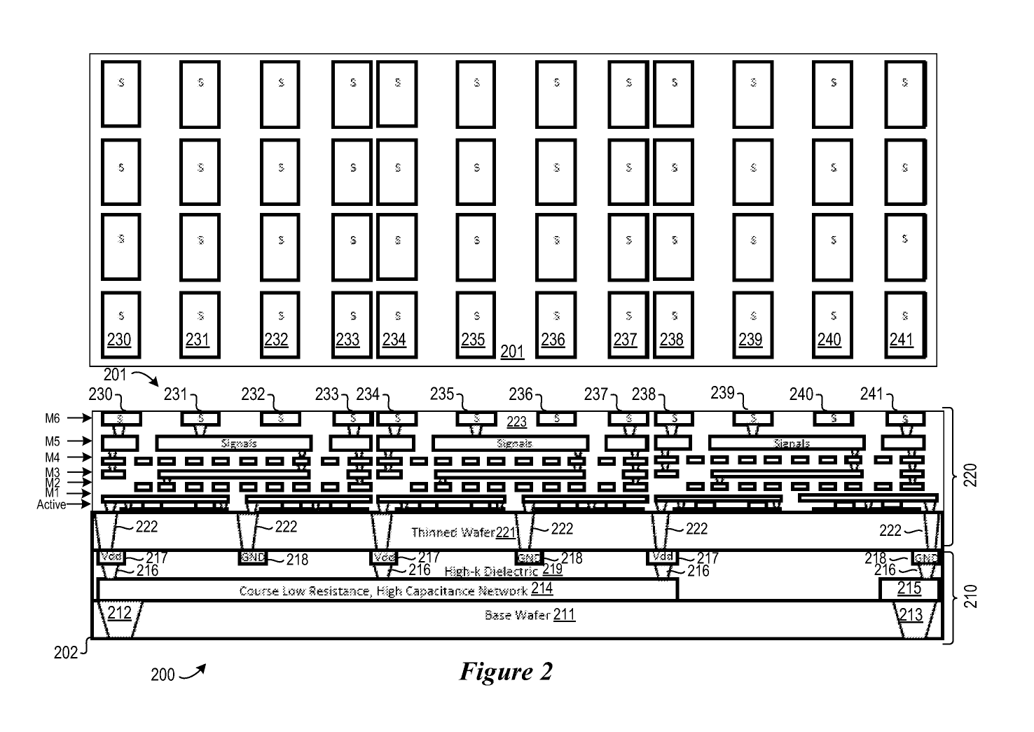

Referring now to FIG. 2, there is shown a simplified top view 201 and side view 202 of a stacked wafer/die 200 in which active circuits formed on an active wafer/die are connected to power lines through backside through silicon vias and a power delivery wafer attached to the backside of the active wafer. As illustrated, the stacked die or wafer (hereinafter, wafer) includes a base wafer 211 and a thinned wafer 221 that are stacked together by means of wafer bond techniques to attach an active wafer structure 220 to a power delivery wafer structure 210 which are each fabricated with separate semiconductor processing steps.

The active wafer structure 220 includes a thinned wafer substrate 221. For example, the thinned wafer substrate 221 may be formed with a crystalline silicon substrate having a predetermined orientation that is selected to provide enhanced charge carrier mobility for NMOS devices and PMOS devices as desired. Prior to thinning the wafer substrate 221, active circuit components (not shown), such as logic elements, transistors, memory elements, redistribution elements, contact areas, etc. are integrated within or on the surface of the wafer substrate 221 using any desired fabrication processes, such as deposition, growth, masking, patterning, etching, implantation, doping, etc. In addition, a plurality of through wafer vias or through silicon vias 222 are formed in the thinned wafer substrate 221 for purposes of making electrical contact with power lines in the power delivery wafer structure 210. As is known to those skilled in the art, through wafer vias 222 may be formed by a variety of techniques, such as, for example, a laser process, a dry etch process, a photoelectrochemical process, etc. or a combination of these processes. For example, through wafer vias are vias 222 may be formed by etching holes or openings in the wafer substrate 221 which do not extend completely through the wafer, and then filling the holes with one or more conductive or metal materials or layers. When the wafer substrate 221 is subsequently thinned, the vias 222 are exposed at the bottom of the thinned wafer substrate 221 and positioned to enable electrical interconnection between circuit components (e.g. bond pads, etc.) formed on opposite sides of the thinned wafer substrate 221. In addition, the active circuits are connected to signal lines S on the top or front side of the active wafer structure 220 through a multi-layer interconnect structure of multiple metal layers (e.g., M1-M6) formed in dielectric layer(s) or materials 223. As illustrated with the top view 201, all or substantially all of the contact layers 230-241, etc. on the top or front side of the active wafer structure 220 are available to provide I/O signals to the active circuits to the extent that power (e.g., Vdd and GND) is delivered through the backside of the thinned wafer substrate 221.

The power delivery wafer structure 210 includes a base wafer substrate 211 which may be formed with any desired crystalline silicon substrate or other semiconductor material. In the power delivery wafer structure 210, a power conductor network is formed using any desired fabrication processes to selectively form layers of conductive and dielectric materials for delivering power (e.g., Vdd, GND) from the backside of the base wafer substrate 211 (as shown), though other power routing paths through the base wafer substrate 211 could also be used. For example, a plurality of through wafer vias or through silicon vias (e.g., 212, 213) may formed in the base wafer substrate 211 for purposes of making electrical contact with external power sources (e.g., Vdd, GND) to supply electrical power to the active circuit components in the active wafer structure 220. The size, shape, and configuration such as the width and depth of the TSVs 212, 213 may vary depending upon the particular application. In general terms, through wafer vias are vias 212, 213 are formed by etching holes or openings in the base wafer substrate 211 that are larger than the via openings 222 in the thinned wafer substrate 221, and then filling the holes with one or more conductive or metal materials or layers to enable electrical interconnection between opposite sides of the base wafer substrate 211. On the top or front surface of the base wafer substrate 211, one or more layers of conductive metal and dielectric material are selectively formed to provide a power network layer(s) 214, 215, such as be depositing, patterning and etching a relatively thick metal layer to form a coarse low resistance, high capacitance network. In an example fabrication sequence, a first layer of high-k dielectric material that is formed or deposited over the base wafer substrate 211 is selectively patterned and etched to form openings over at least the previously formed TSVs 212, 213 in which one or more conductive metal layers are deposited and polished to form at least a first power conductor (e.g., Vdd conductor 214) and a second power conductor (e.g., GND conductor 215). Additional layers of dielectric and conductive material are successively fabricated to form conductive via structures 216 and power contact layers 217, 218 in the high-k dielectric layer(s) 219, such that the Vdd power conductor layer(s) 217 and GND power conductor layer(s) 218 are respectively aligned with the corresponding through wafer vias are vias 222. As will be appreciated, the power delivery wafer structure 210 can be produced inexpensively in a low-cost fab since the power delivery wafer structure 210 does not contain active circuits and only has relatively easy to manufacture geometries.

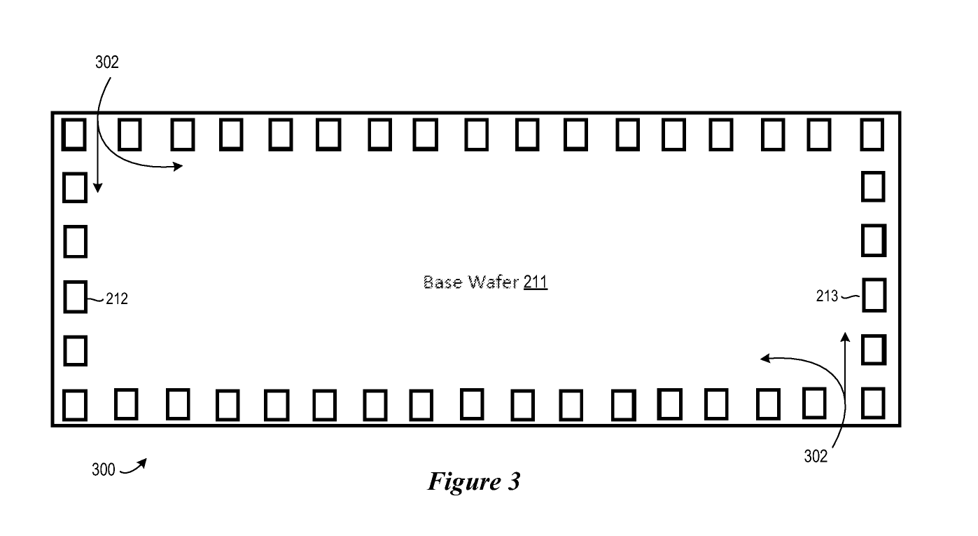

The completed active wafer structure 220 is attached or bonded to the power delivery wafer structure 210 to form the stacked wafer/die 200. In an example implementation, a wafer bonding process bonds the backside surface of the active wafer structure 220 to the facing top or front side of the power delivery wafer structure 210 by applying pressure and heat in accordance with well-established bond techniques. As will be appreciated, one or more dielectric layers may be formed at the interface between the active wafer structure 220 and power delivery wafer structure 210 to promote adhesion between the structures 210, 220, provided that electrical contact is maintained between the power contact layers 217, 218 and the TSVs 222. In other embodiments, the wafer substrate 221 (which may include TSVs 222) is bonded to the power delivery wafer structure 210, where the wafer substrate 221 may then be processed to cleave or otherwise thin the wafer substrate 221j and then form the active circuits multi-layer interconnect structure of multiple metal layers (e.g., M1-M6) formed in dielectric layer(s) or materials 223. In either case, the completed stacked wafer/die 200 is subsequently processed to singulate or separate individual die from one another by cutting or sawing the stacked wafer/die 200 so that each individual die includes its own backside TSVs 212, 213 for delivering power to the active circuits from the backside of the die while I/O signals are delivered from the front or topside of the die. While the power connect vias 212, 213 can be formed at any desired location on the backside of the base wafer substrate 211, in selected embodiments illustrated with reference to the simplified plan view shown in FIG. 3, the power connect vias can be arrayed as a peripheral power connect ring 302 that is formed in the backside of the base wafer substrate 211 of the power delivery wafer structure 210 for connecting to external power (e.g., Vdd, GND).

As seen from the foregoing, the stacked wafer/die 200 uses through silicon via technology to bring power and ground voltages onto the wafer primarily through the backside of the wafer, in contrast with conventional silicon processing where power is brought in through the top of the wafer using multiple metallization layers which consume much of the available routing resources, create congestion, and cause resistive losses through the fine metal interconnect layers. By delivering power and ground voltages primarily through the backside of the wafer to reduce the routing and vias on the front side of the wafer, higher device and routing density can be achieved on the primary/active wafer as well as excellent power/ground integrity. In addition, electro-migration concerns in the power network are reduced with backside power delivery. The reduction in the number of power routing layers required on the primary/active wafer also allows optimization of the signal routing layers in the primary/active wafer without requiring a compromise between power delivery and signal interconnect lines.

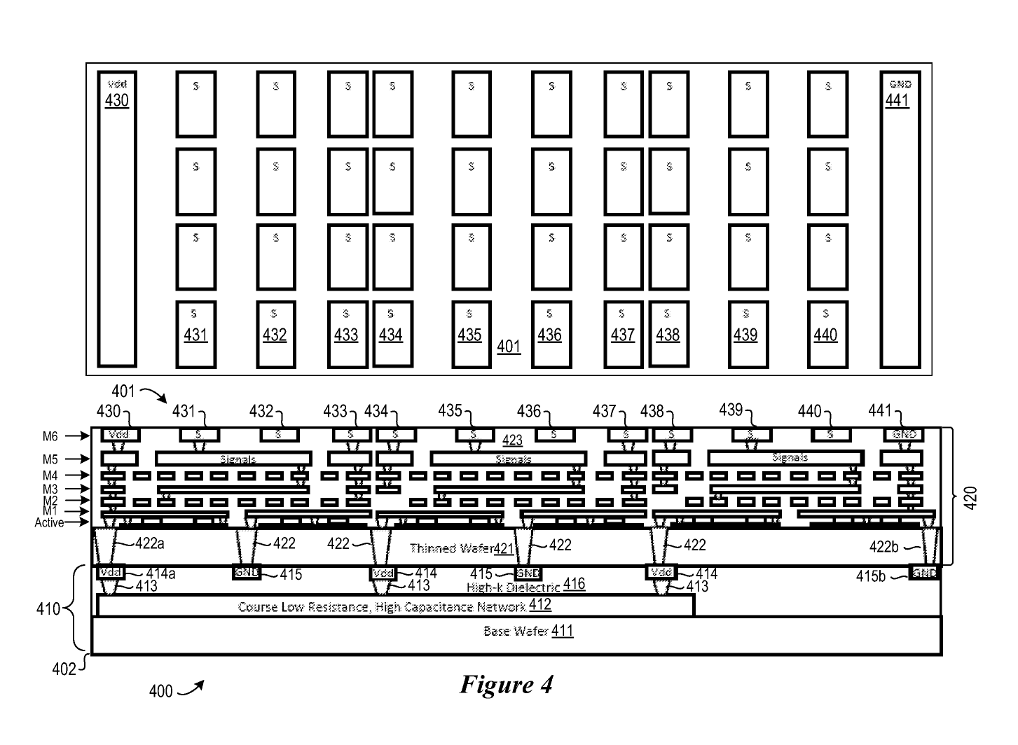

While selected embodiments described with reference to FIG. 2 show that all of the power network may be delivered from the backside of the active wafer structure 220, it will be appreciated that advantages may also be obtained by using backside TSVs significantly reduce the power delivery network from the front or top side of the active wafer structure 220. To illustrate how the upper layer power network may be reduced, reference is now made to FIG. 4 which illustrates a simplified top view 401 and side view 402 of a stacked wafer/die 400 in which a power delivery wafer/die 410 is stacked on the backside of the active wafer/die 420. As formed, power (e.g., Vdd and GND) is supplied at the periphery of the stacked wafer/die 400 through the front side of the active wafer/die 420 through contact layers 430 and 441 and then distributed through the backside of the active wafer/die 420 using TSVs formed in the active wafer/die 420, alone or in combination with a power pump circuit (not shown). As illustrated, the stacked die or wafer 400 includes a base wafer structure 410 and a thinned wafer structure 420 that are fabricated with separate semiconductor processing steps and then stacked together by means of wafer bond techniques. As will be appreciated, the power delivery wafer structure 420 may be processed as the basic or handle substrate while the active wafer structure 410 is processed as a donor substrate, or vice versa.

In selected embodiments, the power delivery wafer structure 410 is formed with a base wafer substrate 411 which may be formed with any desired crystalline silicon substrate or other suitable substrate material. On the power delivery wafer structure 410, a power conductor network is formed using any desired fabrication processes to selectively form layers of conductive and dielectric materials for delivering power (e.g., Vdd, GND) that is supplied from the peripheral power contact layers 430 and 441 in the active wafer/die 420 so that the supplied power is delivered to the backside of the active wafer/die 420 (as shown). For example, one or more layers of conductive metal and dielectric material are selectively formed on the top or front surface of the base wafer substrate 411 to provide one or more power network layers 412, such as be depositing, patterning and etching a relatively thick metal layer to form a coarse low resistance, high capacitance network. In an example fabrication sequence, a first layer of high-k dielectric material that is formed or deposited over the base wafer substrate 411 is selectively patterned and etched to form contact openings in which one or more conductive metal layers are deposited and polished to form at least a first power conductor (e.g., Vdd conductor 412). Additional layers of dielectric and conductive material are successively fabricated to form conductive via structures 413 and power contact layers 414, 415 in the high-k dielectric layer(s) 416, such that Vdd power conductor layer(s) 414 and GND power conductor layer(s) 415 are exposed at the top of the power delivery wafer structure 410. Because the power delivery wafer structure 410 does not contain active circuits and only has relatively easy to manufacture geometries, it can be produced inexpensively in a low-cost fab since.

The active wafer structure 420 is separately fabricated to include a wafer substrate 421 with a crystalline silicon substrate having a predetermined orientation that is selected to provide enhanced charge carrier mobility for NMOS devices and PMOS devices as desired. In the wafer substrate 421, a plurality of through wafer vias or through silicon vias 422 are formed for purposes of making electrical contact with the power contact layers 414, 415 in the power delivery wafer structure 410 when subsequently attached thereto. As is known to those skilled in the art, through wafer vias 422 may be formed by a variety of techniques, such as, for example, a laser process, a dry etch process, a photoelectrochemical process, etc. or a combination of these processes. In general terms, through wafer vias are vias 422 are formed by etching holes or openings in the wafer substrate 421 and then filling the holes with one or more conductive or metal materials or layers.

The wafer substrate 421 and TSVs 422 may then be bonded to the power delivery wafer structure 410 using a wafer bonding process which bonds the backside surface of the wafer substrate 421 to the facing top or front side of the power delivery wafer structure 410 by applying pressure and heat in accordance with well-established bond techniques. As will be appreciated, one or more dielectric layers may be formed at the interface between the wafer substrate 421 and power delivery wafer structure 410 to promote adhesion therebetween, provided that electrical contact is maintained between the power contact layers 414, 415 and the TSVs 422. The wafer substrate 421 may then be processed to cleave or otherwise thin the wafer substrate 421.

Prior to bonding the active wafer structure 420 and wafer substrate 421 and any thinning of the active wafer structure 420, it will be appreciated that active circuit components (not shown) may be formed within or on the surface of the thinned wafer substrate 421 using any desired fabrication processes, followed by formation of a multi-layer interconnect structure of multiple metal layers (e.g., M1-M6) formed in dielectric layer(s) or materials 423, thereby forming an active wafer structure 420. In this way, the integrated circuit processing of the active wafer structure 420 is completed before the wafer bonding or thinning operations. As formed, the multi-layer interconnect structure connects the active circuits formed in the thinned wafer substrate 421 to signal lines S 431-440 on the top or front side of the active wafer structure 420. In addition, one or more first power conductor layers 430, 441 formed at the periphery of the active wafer structure 420 are used to bring one or more reference or power voltages (e.g., Vdd, GND) down from the top or front side of the active wafer structure 420 through the multiple metal layers (e.g., M1-M6) for delivery to the power delivery wafer/die for delivery to the backside of the active wafer structure 420. For example, Vdd power is routed from the peripheral power conductor layer 430 on the front side of the active wafer structure 420, down through the TSV 422a in the active wafer structure 420 and to the peripheral power contact layer 414a and associated via 413 in the power delivery wafer structure 410 for delivery to the power network layer(s) 412 which distribute Vdd power through vias 413 and power contact layers 414 to the backside of the active wafer structure 420. In similar fashion, GND (or Vss) power is routed from the peripheral power conductor layer 441 on the front side of the active wafer structure 420, down through the TSV 422b in the active wafer structure 420 and to the peripheral power contact layer 415b in the power delivery wafer structure 410 for delivery through the power contact layer 415 to the backside of the active wafer structure 420.

After forming or attaching the active wafer structure 420 on the power delivery wafer structure 410, the completed stacked wafer/die 400 is subsequently processed to singulate or separate individual die from one another by cutting or sawing the stacked wafer/die 400 so that each individual die includes a limited number of power conductor layers (e.g., 430, 441) on the front or topside of the active wafer structure 420 for delivering power to the power delivery wafer structure 410 which in turn distributes power to the active circuits from the backside of the thinned wafer substrate 421 while I/O signals are delivered from the signal lines S 431-440 on the top or front side of the active wafer structure 420. As illustrated with the top view 401, substantially all of the contact layers 431-440, etc. on the top or front side of the active wafer structure 420 are available to provide I/O signals to the active circuits to the extent that power (e.g., Vdd and GND) is delivered through a reduced number of contact layers 430, 441 on the front side of the active wafer structure 420.

Although the described exemplary embodiments disclosed herein are directed to selected stacked die embodiments and methods for fabricating same, the present invention is not necessarily limited to the example embodiments which illustrate inventive aspects of the present invention that are applicable to a wide variety of memory types, processes and/or designs. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

Accordingly, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

What is claimed is:

1. A stacked die device, comprising:
a power delivery die comprising power and ground conductors for connection to one or more external power and ground sources; and
an active circuit die connected to the power delivery die, where the active circuit die comprises power and ground routings connected to circuit components formed on the active circuit die and connected to receive power from the power and ground conductors in the power delivery die through a first plurality of conductive via structures formed in the active circuit die.

2. The stacked die device of claim 1, where the power delivery die comprises a power conductor and a ground conductor formed in one or more high-k dielectric layers on a base substrate layer for connecting the external power and ground sources to the first plurality of conductive via structures formed in the active circuit die.

3. The stacked die device of claim 2, where the power delivery die comprises a second plurality of conductive via structures formed in the base substrate layer for connecting the power conductor and a ground conductor to the external power and ground sources.

4. The stacked die device of claim 2, where the active circuit die comprises a metal interconnect structure formed on a substrate layer, where the metal interconnect structure comprises a plurality of signal input/output lines, a conductive power contact structure, and a conductive ground contact structure for connecting the external power and ground sources to the power and ground conductors in the power delivery die.

5. The stacked die device of claim 4, where all of the metal interconnect structure is used to connect the plurality of signal input/output lines to the circuit components except for the conductive power contact structure and the conductive ground contact structure.

6. The stacked die device of claim 1, where the active circuit die comprises a metal interconnect structure formed on a substrate layer, where all of the metal interconnect structure is used to connect the plurality of signal input/output lines to the circuit components.

7. The stacked die device of claim 1, where the power delivery die provides backside power to the active circuit die with a network of low resistance, high capacitance power and ground conductors for connecting the one or more external power and ground sources to the first plurality of conductive via structures formed in the active circuit die.

8. The stacked die device of claim 1, where the active circuit die comprises coarse through silicon vias formed in a silicon substrate that are connected to receive power from the power and ground conductors in the power delivery die.

9. The stacked die device of claim 1, where the active circuit die comprises a metal interconnect structure with first and second conductor layers formed at the periphery of the metal interconnect structure for bringing power and ground voltages down through multiple metal layers in the metal interconnect structure for delivery to the power and ground conductors in the power delivery die.

10. The stacked die device of claim 1, where the power delivery die comprises a plurality of through silicon via structures formed peripherally around a base silicon substrate layer for bringing power and ground voltages through the base silicon substrate layer for delivery to the power and ground conductors in the power delivery die.

11. A method for forming a stacked device, comprising:
providing a power delivery wafer comprising power and ground routings formed in one or more dielectric layers on a top surface of the power delivery wafer for connection to one or more external power and ground sources;
providing an active circuit wafer having first and second surfaces with active circuits formed on the first surface of the active circuit wafer and with a plurality of conductive via structures formed in the active circuit wafer to form conductors between the first and second surfaces;
bonding the active circuit wafer and the power delivery wafer to electrically connect the plurality of conductive via structures formed in the active circuit wafer with the power and ground routings in the power delivery wafer; and
forming power and ground routings over the first surface of the active circuit wafer to connect the active circuits the power and ground routings in the power delivery wafer through the plurality of conductive via structures formed in the active circuit wafer.

12. The method of claim 11, where providing the power delivery wafer comprises forming power and ground routings with a coarse network of low resistance, high capacitance power and ground conductors formed in one or more high-k dielectric layers on a base semiconductor substrate.

13. The method of claim 12, where providing the power delivery wafer comprises forming a plurality of conductive via structures in the base semiconductor substrate for connecting the power and ground conductors to external power and ground sources.

14. The method of claim 12, where forming power and ground routings over the first surface of the active circuit wafer comprises forming a metal interconnect structure in one or more dielectric layers on a thinned substrate, where the metal interconnect structure comprises a plurality of signal input/output lines, a conductive power contact structure for connecting an external power source to the power conductor in the power delivery wafer, and a conductive ground contact structure for connecting an external ground source to the ground conductor in the power delivery wafer.

15. The method of claim 14, where all of the metal interconnect structure is used to connect the plurality of signal input/output lines to the active circuits except for the conductive power contact structure and the conductive ground contact structure.

16. The method of claim 11, where forming power and ground routings over the first surface of the active circuit wafer comprises forming a metal interconnect structure in one or more dielectric layers on a thinned substrate, where all of the metal interconnect structure is used to connect the plurality of signal input/output lines to the active circuits.

17. The method of claim 11, where providing the active circuit wafer with the plurality of conductive via structures comprises:
etching a plurality of openings in the active circuit wafer;
filling the plurality of openings with one or more conductive materials to form the plurality of conductive via structures; and
thinning the active circuit wafer to expose the plurality of conductive via structures at the second surface of the active circuit wafer.

19. The method of claim 11, where forming power and ground routings over the first surface of the active circuit wafer comprises forming a metal interconnect structure with first and second conductor layers formed at the periphery of the metal interconnect structure for bringing power and ground voltages down through multiple metal layers in the metal interconnect structure for delivery to the power and ground routings in the power delivery wafer.

20. A stacked die assembly comprising:
a first semiconductor die having topside and backside surfaces with active circuit components formed at the topside surface and electrically connected to a plurality of relative thin conductive via structures formed in the first semiconductor die to form a distributed array of power and ground conductors between the topside and backside surfaces;
a second backside power delivery die affixed to the backside of the first semiconductor die and comprising integrated capacitors and power and ground conductors formed in one or more high-k dielectric layers with relatively thick metallization layers for connecting the plurality of conductive via structures to one or more external power and ground sources.
